(19) United States
(12) Patent Application Publication
(10) Pub. No.: US 2015/0216064 A1
(43) Pub. Date: Jul. 30, 2015

(54) SUPPORTING APPARATUS OF HOUSING

(71) Applicant: Da-Chung Wu, Taipei City (TW)

(72) Inventor: Da-Chung Wu, Taipei City (TW)

(21) Appl. No.: 14/168,510

(22) Filed: Jan. 30, 2014

(51) Int. Cl. H05K 5/02; H05K 5/00

(52) U.S. Cl. CPC H05K 5/0234; H05K 5/0086

(57) ABSTRACT

A housing supporting apparatus includes: a base-plate body having a base-plate axis; a connection plate body having one end formed with a connection plate axis and pivotally connected to one end of the base-plate body; a first supporting plate having a first axis pivotally connected to the one end of the connection plate body; and a second supporting plate having a second axis pivotally connected to one end of the first supporting plate. The second supporting plate has one end pivotally connected to the base-plate axis.

### BACKGROUND OF THE INVENTION

(1) Field of the Invention

The invention relates to a supporting apparatus of a housing, and more particularly to a housing supporting apparatus applicable to a tablet or a smart phone.

(2) Description of the Prior Art

At present, most of the supporting structures applied to the tablet devices utilize a housing combined with a supporting structure to form the support. The supporting structures for the available products pertain to the externally independent structures, and the users feel inconvenient when carrying or using the supporting structures.

Furthermore, another product has the housing combined with the protection sheath structure formed by the front and rear plate bodies, and the front and rear plate bodies cover the front side and backside of the tablet device to achieve the protection effect. The front plate body has a folding line for the user to turn over the front plate body behind the tablet device to form the support. Alternatively, the folding line is formed on the connection portion between the rear plate body and the housing, so that the user can turn over the rear plate body to make the tablet device stand on the front plate body to form the support. However, no matter which mode of protection sheath is used, the externally independent supporting apparatus is still used to support the tablet device, such as a tablet, a personal digital assistant (PDA), a smart phone or the like. Therefore, there are more external components, and the overall weight and thickness of the tablet device are increased to increase the loading of the user who is carrying and using the device. In addition, using the supporting structure, formed after turning over the plate body, requires the sufficient plane space for the placement of the supported tablet device, so that the use environment is correspondingly restricted.

### SUMMARY OF THE INVENTION

Most of the known tablet device supporting structures utilize a component external to a housing to achieve the supporting effect, and cannot easily satisfy the slim and light and portable requirements of the user on the handheld digital device (tablet device).

Therefore, it is necessary to develop a housing supporting apparatus for supporting a tablet device without increasing the user's loading. The housing supporting apparatus can provide the supporting effect upon use, and can be easily retracted and stored in the housing when not used to decrease the user's carry loading so that the housing supporting apparatus can be applied to the more diversified environment.

A housing supporting apparatus of the invention includes: a base-plate body having a base-plate axis; a connection plate body having one end, which is formed with a connection plate axis and pivotally connected to one end of the base-plate body; a first supporting plate having a first axis pivotally connected to the one end of the connection plate body; and a second supporting plate having a second axis pivotally connected to one end of the first supporting plate, wherein one end of the second supporting plate is pivotally connected to the base-plate axis.

The effect of the invention can provide the design of the foldable housing supporting apparatus for the user to support his/her tablet device. The housing supporting apparatus can have the first supporting plate and the second supporting plate folded to provide the supporting effect upon use, and can also be stored in the accommodating slot of the housing when not used, thereby decreasing the loading of carrying the tablet device.

Preferably, the first supporting plate further comprises a first right side and a first left side, and the slope of the first right side may be equal to, greater than or smaller than that of the first left side. Thus, the user can select the suitable slope according to the requirement, and the same or different slanting effects can be generated when the user uses the tablet device in the transversal standing state, thereby enhancing the comfort in use.

Preferably, the second supporting plate further comprises a second right side and a second left side, and the second right side and the second left side may also correspond to the first right side and the first left side to enhance the stability of supporting the tablet device upon use.

Further aspects, objects, and desirable features of the invention will be better understood from the detailed description and drawings that follow in which various embodiments of the disclosed invention are illustrated by way of examples.

### BRIEF DESCRIPTION OF THE DRAWINGS

FIG. 1 is a pictorial view of the invention.

FIG. 2 is a pictorial view of the invention after being folded.

FIG. 3 is a cross-sectional view of the invention.

FIG. 4 is a cross-sectional view of the invention after being folded.

FIG. 5 is a pictorial view of the invention at another viewing angle.

FIG. 6 is a pictorial view of the invention at another viewing angle.

FIG. 7 is a pictorial view of the invention at another viewing angle.

FIG. 8 is a pictorial view of the invention at another viewing angle.

FIG. 9 is a pictorial view of another embodiment of the invention.

FIG. 10 is a pictorial view of another embodiment of the invention after being folded.

FIG. 11 is a pictorial view of still another embodiment of the invention

FIG. 12 is a pictorial view of still another embodiment of the invention after being folded.

### DETAILED DESCRIPTION OF THE PREFERRED EMBODIMENTS

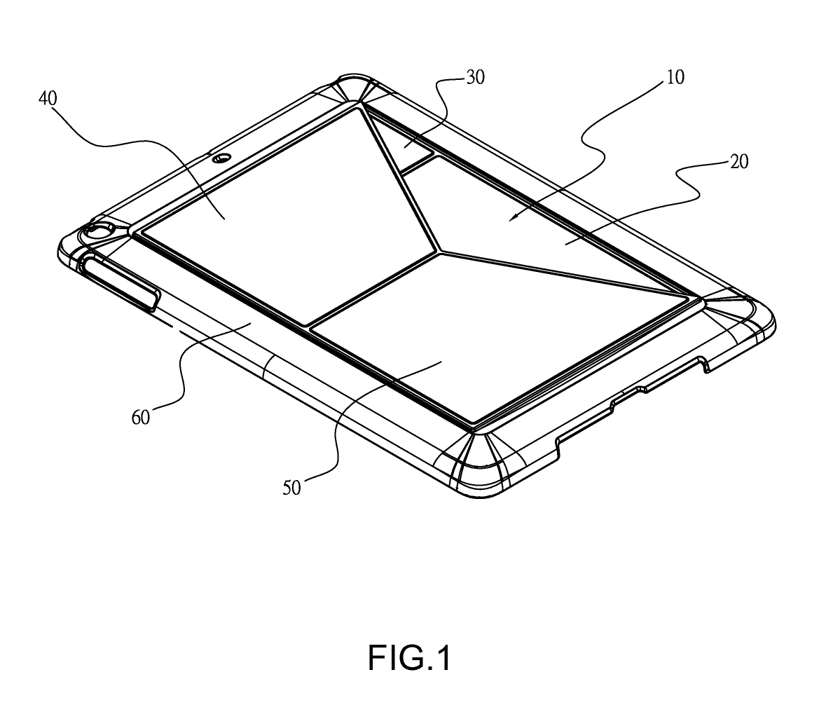

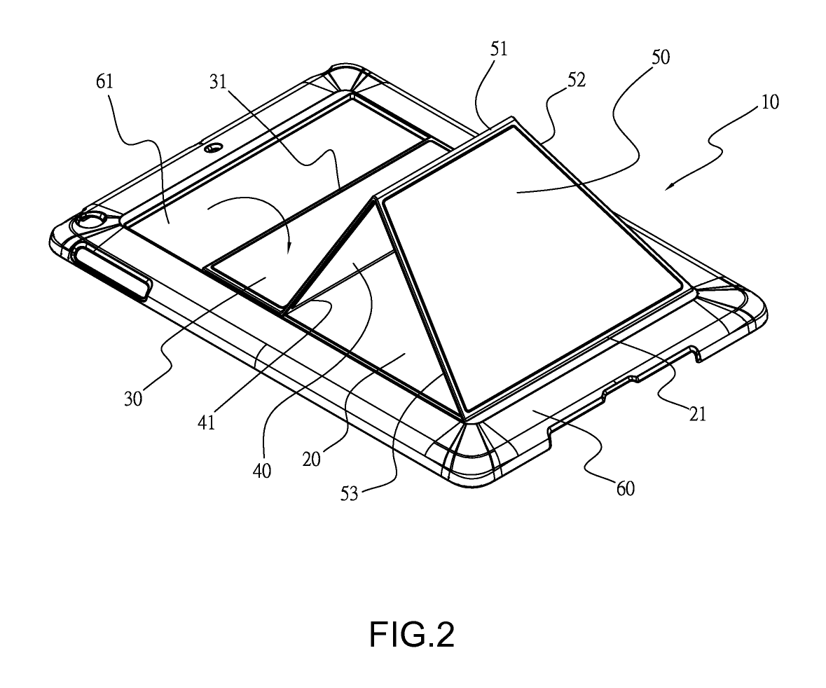

Referring to the pictorial view of FIG. 1 of the invention and the pictorial view of FIG. 2 of the invention after being folded, a housing supporting apparatus 10 of the invention has the main components including: a base-plate body 20 having a base-plate axis 21; a connection plate body 30 having one end formed with a connection plate axis 31 and pivotally connected to one end of the base-plate body 20; a first supporting plate 40 having a first axis 41 pivotally connected to the one end of the connection plate body 30; and a second supporting plate 50 having a second axis 51 pivotally connected to one end of the first supporting plate 40. One end of the second supporting plate 50 is pivotally connected to the base-plate axis 21.

It is to be noted that the pivotal connection disclosed in this invention includes, but without limitation to, performing the flexural stress concentration between two constituent elements in a thinned manner. This means that the maximum deformation is generated using a thinned portion to have the bending or folding effect. In detail, despite whether the base-plate body 20, the connection plate body 30, the first supporting plate 40 and the second supporting plate 50 are made of the same material, the flexural stress concentration can be performed in the thinned manner. This effect causes the two constituent elements to generate the bending or folding effect, as shown in FIG. 2. Furthermore, the invention also does not exclude other methods from performing the pivotal connection. For example, the pivotal connection effect can be achieved using a rotating shaft or the deformation amount of the material itself.

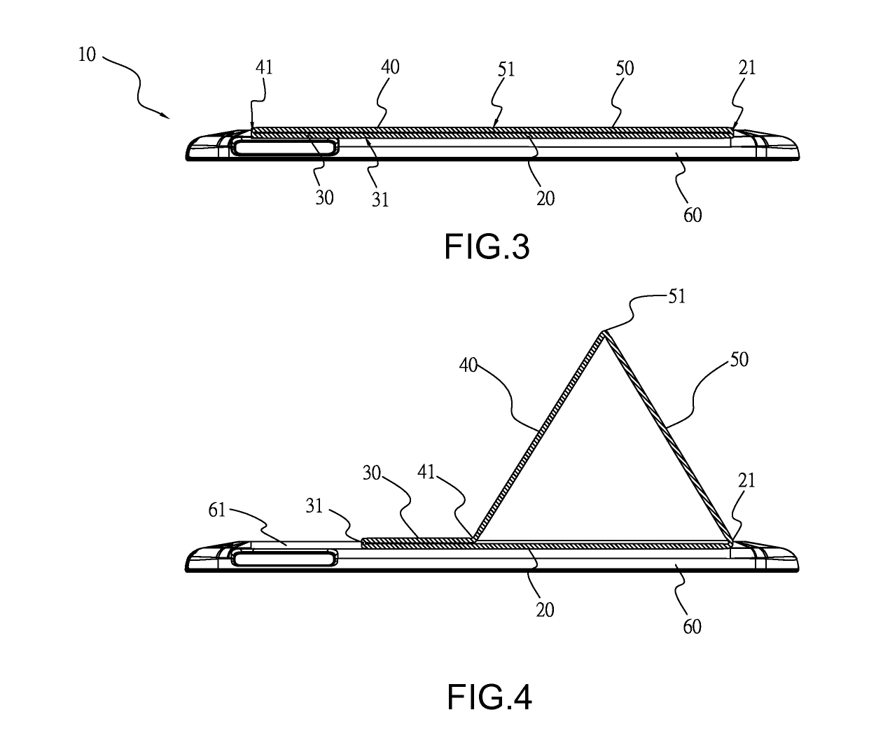

Please refer to the cross-sectional view of FIG. 3 of the invention and the cross-sectional view of FIG. 4 of the invention after being folded. Before the housing supporting apparatus 10 of the invention deforms, the one end of the first supporting plate 40 of the invention is pivotally connected to the second supporting plate 50 through the second axis 51. In addition, the one end of the connection plate body 30 is pivotally connected to the one end of the base-plate body 20 through the connection plate axis 31. The first axis 41 is pivotally connected to one end of the connection plate body 30, and the other end of the base-plate body 20 is pivotally connected to the second supporting plate 50.

In this invention, the connection plate body 30 may be composed of a permanent magnet. As shown in FIG. 2 representing the folded state, the connection plate body 30 may be tightly connected to a housing 60 made of any metal. The personal digital assistant (PDA), tablet or smart phone can achieve the effect of supporting the digital product according to the disclosure of this invention without difficulty. Preferably, as shown in FIG. 2, the housing 60 may be formed with an accommodating slot 61. Consequently, when this invention is folded, as shown in the state of FIG. 3, the overall thickness cannot be increased.

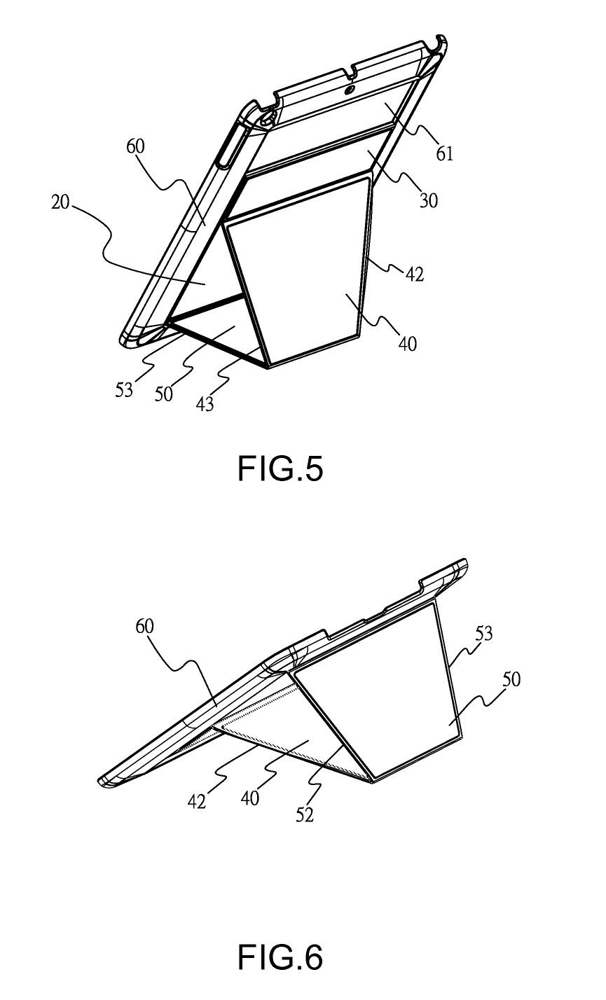

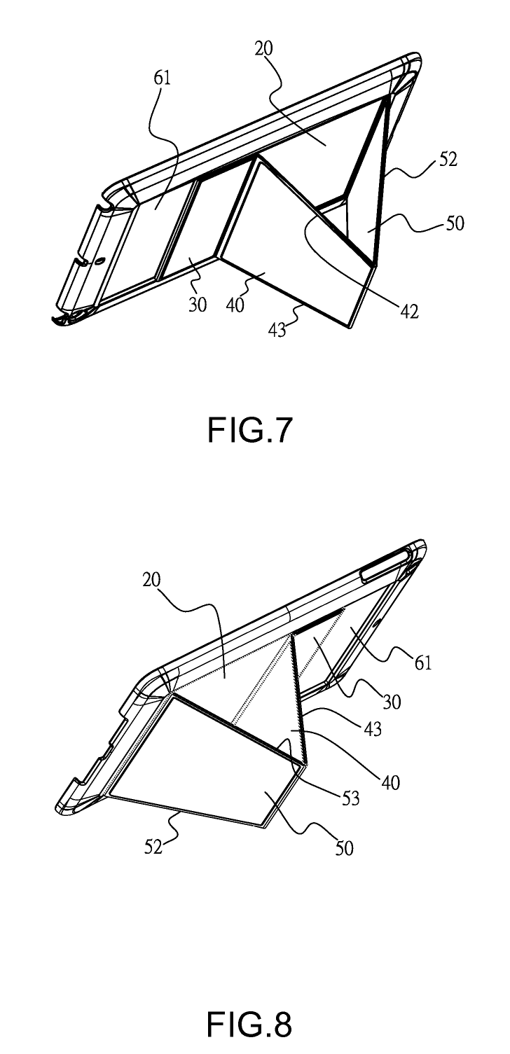

Please refer to the pictorial views of FIGS. 5 to 8 of the invention at another viewing angle. FIGS. 5 to 8 represent the state where the folding function of the invention is enabled. The accommodating slot 61 of the housing 60 may just accommodate all constituent elements of the invention. When the folding function of the invention is enabled, the accommodating slot 61 needs to expose a small space approaching the connection plate body 30.

The connection plate body 30 may be substantially constituted by a permanent magnet. Preferably, the outer surface of the connection plate body 30 may also be covered with a rubber or plastic layer to make the connection plate body 30 and other constituent elements have the same material.

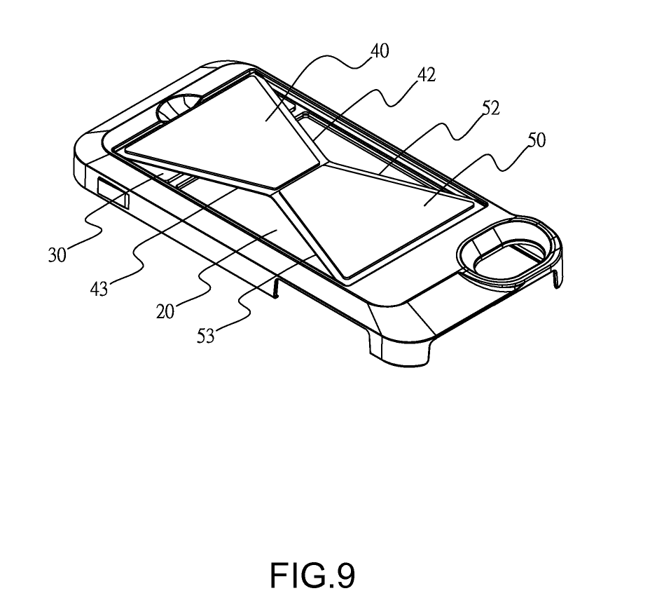

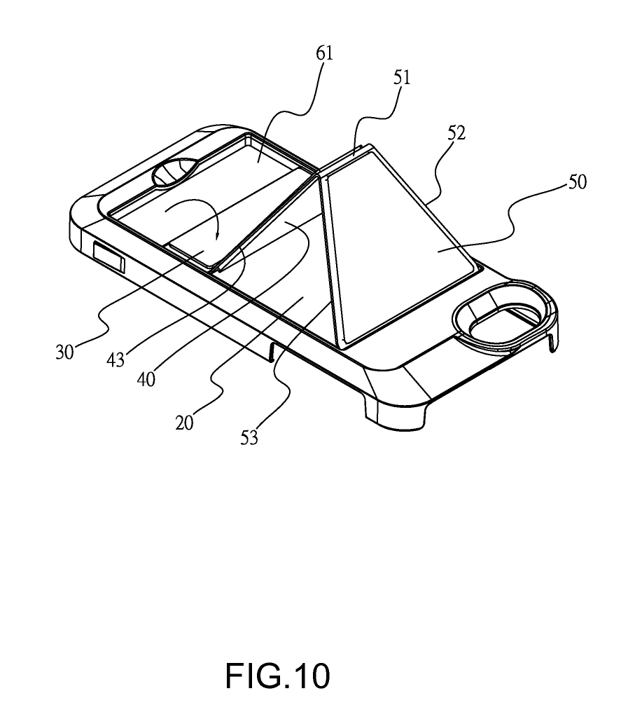

Please refer to the pictorial views of FIGS. 9 and 10 of the invention, the first supporting plate 40 further includes a first right side 42 and a first left side 43. The second supporting plate 50 further includes a second right side 52 and a second left side 53.

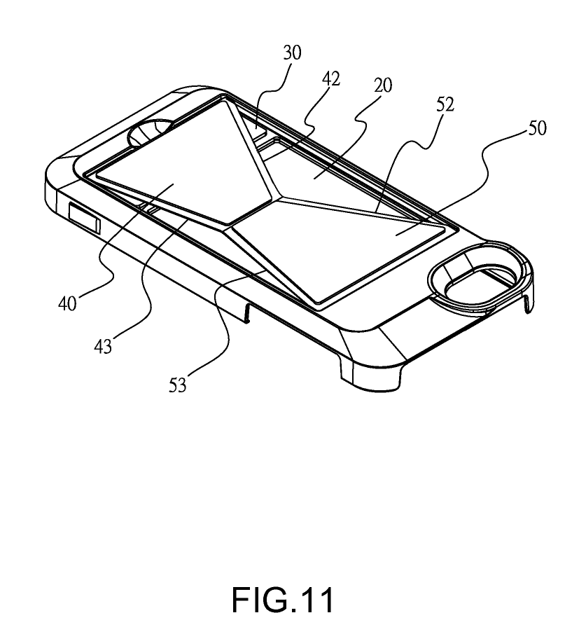

Please refer to pictorial views of FIGS. 9 and 11 of the invention of another embodiment and compare FIG. 9 with FIG. 11. The slope of the first right side 42 of the invention may be configured to be greater than that of the first left side 43. Alternatively, the slope of the first right side 42 may be configured to be smaller than that of the first left side 43. The slope of the second right side 52 of the invention may be configured to be greater than that of the second left side 53. Alternatively, the slope of the second right side 52 may be configured to be smaller than that of the second left side 53.

Please refer to FIG. 9 and compare FIG. 9 with FIG. 11, the invention may constitute a V-shaped right lateral side according to the matching of the slopes of the first right side 42 and the second right side 52. Similarly, the invention may constitute a V-shaped left lateral side according to the matching of the slopes of the first left side 43 and the second left side 53.

As shown in FIG. 9, the first right side 42 and the second right side 52 have the same slope, the first left side 43 and the second left side 53 also have the same slope, the first right side 42 and the first left side 43 also have the same slope, and the second right side 52 and the second left side 53 also have the same slope. Consequently, the invention has the symmetrical effect in the exterior shape.

As shown in FIG. 11, the first right side 42 and the second right side 52 have the same slope, and the first left side 43 and the second left side 53 also have the same slope. However, the first right side 42 and the first left side 43 have different slopes, and the second right side 52 and the second left side 53 have different slopes. Consequently, the invention has the symmetrical effect in the exterior shape.

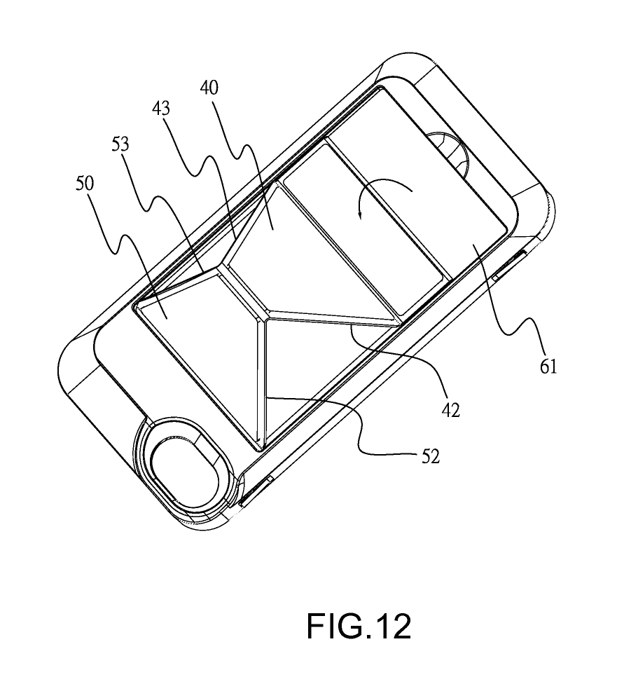

Please refer to the pictorial view of FIG. 1 of the invention and the pictorial view of FIG. 12 of another embodiment of the invention after being folded, the base-plate body 20 may be made of a metal, plastic or rubber material. As disclosed hereinabove, the connection plate body 30 is composed of the permanent magnet, but may have equivalence implemented by way of pseudo mounting or adsorption. The first supporting plate 40 is made of the metal, plastic or rubber material, and the second supporting plate 50 is made of the metal, plastic or rubber material.

New characteristics and advantages of the invention covered by this document have been set forth in the foregoing description. It is to be expressly understood, however, that the drawings are for the purpose of illustration only and are not intended as a definition of the limits of the invention. Changes in methods, shapes, structures or devices may be made in details without exceeding the scope of the invention by those who are skilled in the art. The scope of the invention is, of course, defined in the language in which the appended claims are expressed.

What is claimed is:

1. A housing supporting apparatus, comprising:
a base-plate body having a base-plate axis;
a connection plate body having one end, which is formed with a connection plate axis and pivotally connected to one end of the base-plate body;
a first supporting plate having a first axis pivotally connected to the one end of the connection plate body; and
a second supporting plate having a second axis pivotally connected to one end of the first supporting plate, wherein one end of the second supporting plate is pivotally connected to the base-plate axis.

2. The apparatus according to claim 1, wherein the first supporting plate further comprises a first right side and a first left side.

3. The apparatus according to claim 2, wherein a slope of the first right side is equal to a slope of the first left side.

4. The apparatus according to claim 2, wherein a slope of the first right side is greater than a slope of the first left side.

5. The apparatus according to claim 2, wherein a slope of the first right side is smaller than a slope of the first left side.

6. The apparatus according to claim 1, wherein the second supporting plate further comprises a second right side and a second left side.

7. The apparatus according to claim 6, wherein a slope of the second right side is equal to a slope of the second left side.

8. The apparatus according to claim 6, wherein a slope of the second right side is greater than a slope of the second left side.

9. The apparatus according to claim 6, wherein a slope of the second right side is smaller than a slope of the second left side.

10. The apparatus according to claim 2, wherein the second supporting plate further comprises a second right side and a second left side corresponding to two sides of the first supporting plate.

11. The apparatus according to claim 10, wherein a slope of the second right side is equal to a slope of the second left side.

12. The apparatus according to claim 10, wherein a slope of the second right side is greater than a slope of the second left side.

13. The apparatus according to claim 10, wherein a slope of the second right side is smaller than a slope of the second left side.

14. The apparatus according to claim 1, wherein the base-plate body is made of a metal, plastic or rubber material.

15. The apparatus according to claim 1, wherein the connection plate body is composed of a permanent magnet.

16. The apparatus according to claim 1, wherein the first supporting plate is made of a metal, plastic or rubber material.

17. The apparatus according to claim 2, wherein the first supporting plate is made of a metal, plastic or rubber material.

18. The apparatus according to claim 1, wherein the second supporting plate is made of a metal, plastic or rubber material.

19. The apparatus according to claim 6, wherein the second supporting plate is made of a metal, plastic or rubber material.
